(19) United States
(12) Patent Application Publication
(10) Pub. No.: US 2020/0127238 A1
(43) Pub. Date: Apr. 23, 2020

(54) POLARIZER, DISPLAY SCREEN, AND DISPLAY SCREEN MODULE

(71) Applicant: Wuhan China Star Optoelectronics Semiconductor Display Technology Co., Ltd., Wuhan (CN)

(72) Inventor: Jian YE, Wuhan (CN)

(73) Assignee: Wuhan China Star Optoelectronics Semiconductor Display Technology Co., Ltd., Wuhan (CN)

(21) Appl. No.: 16/326,229

(22) PCT Filed: Nov. 7, 2018
(86) PCT No.: PCT/CN2018/114318

§ 371 Date: Feb. 18, 2019

(30) Foreign Application Priority Data
Oct. 10, 2018 (CN) 201811176624.3

(51) Int. Cl. H01L 51/52; H01L 23/60; H01L 27/32; G06F 3/041

(52) U.S. Cl. CPC H01L 51/5281; H01L 23/60; H01L 51/5253; G02B 5/3025; H01L 27/323; G06F 3/0412; H01L 27/3276

(57) ABSTRACT

A polarizer, a display screen, and a display screen module are provided. The polarizer has a discharge layer and a polarizing layer disposed on the discharge layer, and the discharge layer is connected to a ground trace in the display screen. The display screen has an array substrate, a light emitting device layer, a thin film encapsulation layer, a discharge layer, and a ground trace, the light emitting device layer is disposed on the array substrate, the thin film encapsulation layer is disposed on the light emitting device layer, the discharge layer is disposed on the thin film encapsulation layer, and the discharge layer is connected to the ground trace.

### FIELD OF INVENTION

The present disclosure relates to a display technology field, and in particular to a polarizer, a display screen, and a display screen module.

### BACKGROUND OF INVENTION

Active-matrix organic light emitting diode (AMOLED) display screens have advantages of fast response times, large viewing angles, and flexible display, and is dominant in the display field.

When the AMOLED display screen is in an environment with a lot of static electricity, electronic components disposed in the AMOLED display screen are damaged by large current generated by the static electricity, resulting in an abnormal display of the AMOLED display screen.

### SUMMARY OF INVENTION

An object of the present disclosure is to provide a polarizer, a display screen, and a display screen module, which can improve an antistatic performance of a display.

The present disclosure provides a polarizer used for a display screen, the polarizer comprises a discharge layer, and a polarizing layer disposed on the discharge layer, wherein the discharge layer is connected to a ground trace in the display screen.

In one embodiment of the present disclosure, the discharge layer has an impedance, and a range of the impedance is 10⁸-10⁹ ohms.

The present disclosure provides a display screen, the display screen comprises an array substrate, a light emitting device layer, a thin film encapsulation layer, a discharge layer, and a ground trace, wherein the light emitting device layer is disposed on the array substrate, the thin film encapsulation layer is disposed on the light emitting device layer, the discharge layer is disposed on the thin film encapsulation layer, and the discharge layer is connected to the ground trace.

In one embodiment of the present disclosure, the display screen further comprises a touch electrode layer; the touch electrode layer is disposed on the thin film encapsulation layer, and the discharge layer is disposed on the touch electrode layer; or the touch electrode layer is disposed on the discharge layer; or the touch electrode layer is integrated on the light emitting device layer.

In one embodiment of the present disclosure, the light emitting device layer comprises a cathode layer; the touch electrode layer is formed after the cathode layer is patterned.

In one embodiment of the present disclosure, the display screen further comprises a polarizer; when the touch electrode layer is disposed on the thin film encapsulation layer and the discharge layer is disposed on the touch electrode layer, the polarizer is disposed on the discharge layer; when the touch electrode layer is disposed on the discharge layer, the polarizer is disposed on the touch electrode layer; when the touch electrode layer is integrated on the light emitting device layer, the polarizer is disposed on the discharge layer.

In one embodiment of the present disclosure, the discharge layer has an impedance, and a range of the impedance is 100 to 150 ohms when the touch electrode layer is disposed above the discharge layer; a range of the impedance is 10⁸-10⁹ ohms when the discharge layer is disposed above the touch electrode layer.

In one embodiment of the present disclosure, when the touch electrode layer is disposed on the thin film encapsulation layer, and the discharge layer is disposed on the touch electrode layer, the ground trace includes a ground line, and the ground line is disposed at an edge of the touch electrode layer.

In one embodiment of the present disclosure, when the touch electrode layer is disposed on the discharge layer or the touch electrode layer is integrated on the light emitting device layer, the ground trace includes a source and drain trace, and the source and drain trace is disposed on the array substrate.

In one embodiment of the present disclosure, a composition material of the discharge layer includes a transparent conductive material.

The present disclosure provides a display screen module, the display screen module comprises a display screen, and a flexible circuit board bonded to the display screen, wherein the display screen comprises an array substrate, a light emitting device layer, a thin film encapsulation layer, a discharge layer, and a ground trace; the light emitting device layer is disposed on the array substrate; the thin film encapsulation layer is disposed on the light emitting device layer; the discharge layer is disposed on the thin film encapsulation layer, and the discharge layer is connected to the ground trace; a ground trace in the display screen is grounded through the flexible circuit board.

In one embodiment of the present disclosure, the display screen further comprises a touch electrode layer; the touch electrode layer is disposed on the thin film encapsulation layer, and the discharge layer is disposed on the touch electrode layer; or the touch electrode layer is disposed on the discharge layer; or the touch electrode layer is integrated on the light emitting device layer.

In one embodiment of the present disclosure, the light emitting device layer comprises a cathode layer; the touch electrode layer is formed after the cathode layer is patterned.

In one embodiment of the present disclosure, the display screen further comprises a polarizer; when the touch electrode layer is disposed on the thin film encapsulation layer and the discharge layer is disposed on the touch electrode layer, the polarizer is disposed on the discharge layer; when the touch electrode layer is disposed on the discharge layer, the polarizer is disposed on the touch electrode layer; when the touch electrode layer is integrated on the light emitting device layer, the polarizer is disposed on the discharge layer.

In one embodiment of the present disclosure, the discharge layer has an impedance, and a range of the impedance is 100 to 150 ohms when the touch electrode layer is disposed above the discharge layer; a range of the impedance is 10⁸-10⁹ ohms when the discharge layer is disposed above the touch electrode layer.

In one embodiment of the present disclosure, when the touch electrode layer is disposed on the thin film encapsulation layer, and the discharge layer is disposed on the touch electrode layer, the ground trace includes a ground line, and the ground line is disposed at an edge of the touch electrode layer.

In one embodiment of the present disclosure, when the touch electrode layer is disposed on the discharge layer or the touch electrode layer is integrated on the light emitting device layer, the ground trace includes a source and drain trace, and the source and drain trace is disposed on the array substrate.

In one embodiment of the present disclosure, a composition material of the discharge layer includes a transparent conductive material.

The beneficial effect is that the polarizer, the display screen and the display screen module of the embodiment of the invention disclosure improve the antistatic performance of the display screen by disposing the discharge layer connected to the grounding trace.

### DESCRIPTION OF DRAWINGS

In order to more clearly illustrate the embodiments or the prior art technical solutions embodiment of the present disclosure, will implement the following figures for the cases described in the prior art or require the use of a simple introduction.

Obviously, the following description of the drawings are only some of those of ordinary skill in terms of creative effort without precondition, you can also obtain other drawings based on these drawings embodiments of the present disclosure.

FIG. 1 is a schematic structural diagram of a polarizer according to an embodiment of the present disclosure.

FIG. 2 is a schematic diagram of a first structure of a display screen module according to an embodiment of the present disclosure.

FIG. 3 is a schematic diagram of a second structure of a display screen module according to an embodiment of the present disclosure.

FIG. 4 is a schematic diagram of a third structure of a display screen module according to an embodiment of the present disclosure.

FIG. 5 is a schematic diagram of a fourth structure of a display screen module according to an embodiment of the present disclosure.

FIG. 6 is a schematic diagram of a fifth structure of a display screen module according to an embodiment of the present disclosure.

FIG. 7 is a schematic diagram of a sixth structure of a display screen module according to an embodiment of the present disclosure.

### DETAILED DESCRIPTION OF PREFERRED EMBODIMENTS

Structure and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

In the figures, structurally similar elements are denoted by the same reference numerals.

References to “embodiments” herein mean that the specific features, structures, or characteristics described in connection with the embodiments can be included in at least one embodiment of the invention. The appearances of the phrases in various places in the specification are not necessarily referring to the same embodiments, and are not exclusive or alternative embodiments that are mutually exclusive. Those skilled in the art will understand and implicitly understand that the embodiments described herein can be combined with other embodiments.

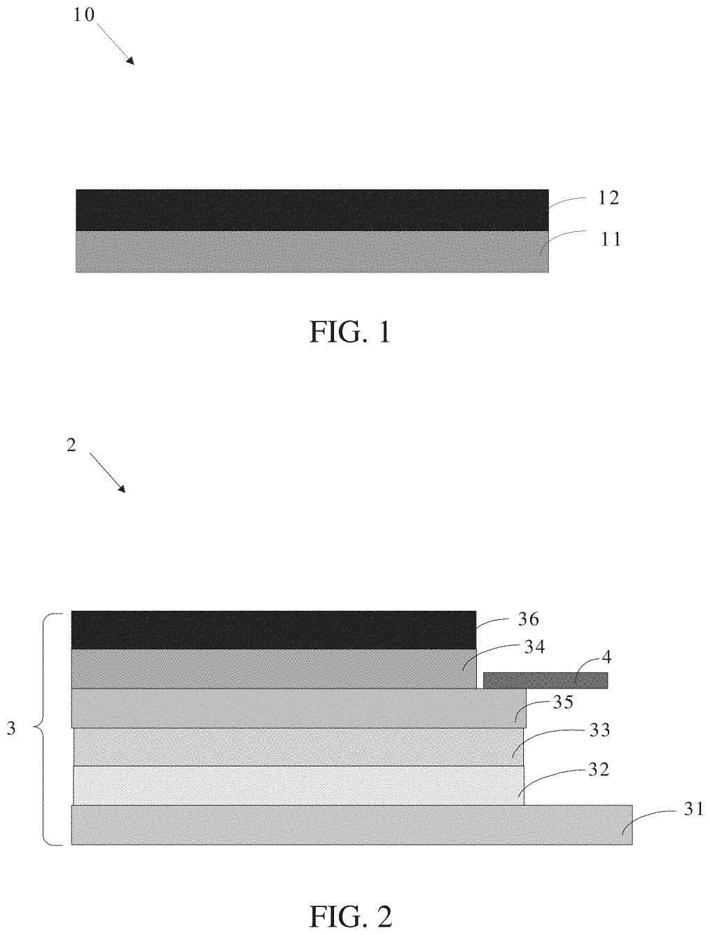

An embodiment of the present disclosure provides a polarizer used for a display screen, wherein the display screen comprises a ground trace, such as ground line, source and drain traces grounded through a flexible circuit board, etc. Referring to FIG. 1, a schematic structural diagram of a polarizer according to an embodiment of the present disclosure is illustrated. The polarizer 1 comprises a discharge layer 11 and a polarizing layer 12, wherein the polarizing layer 12 is disposed on the discharge layer 11.

The polarizing layer 12 is configured to transmit light that vibrates in a certain direction, wherein the polarizing layer 12 is a transmissive polarizing layer, a reflective polarizing layer or a semi-transmissive polarizing layer, and the type of the polarizing layer 12 is not specifically limited herein.

The discharge layer 11 is made of a conductive material, such as a metal material, a conductive non-metal material, a semiconductor material, or the like. In one embodiment, the conductive material is a transparent conductive material, such as indium tin oxide (ITO). In one embodiment, the conductive material is a conductive material having a higher impedance, and a range of the impedance of the discharge layer 11 is 10⁸-10⁹ ohms. The discharge layer 11 is connected to a ground trace in the display screen, wherein the ground trace is a ground line, or a source and drain traces grounded through a flexible circuit board. Specifically, a conductive line can be disposed along a height direction of the display screen of the stacked structure, and the discharge layer 11 is connected to the ground trace through the conductive line.

As described above, when the display screen is in an environment with a lot of static electricity, the discharge layer 11 is discharged through the ground trace to discharge the static electricity received by the display screen.

The polarizing layer provided by the embodiment of the invention disclosure improves antistatic performance of the display screen by disposing a discharge layer connected to the grounding trace in the display screen.

An embodiment of the present disclosure further provides a display screen module. Referring to FIGS. 2-4, schematic diagrams of a structure of a display screen module according to an embodiment of the present disclosure are illustrated. The display screen module comprises a display screen 3 and a flexible circuit board 4 bonded to the display screen 3. The display screen 3 comprises an array substrate 31, a light emitting device layer 32, a thin film encapsulation layer 33, a discharge layer 34, and a ground trace (not shown).

The array substrate 31 includes structures such as a substrate, a buffer layer, and thin film transistors, wherein the substrate is a flexible substrate or a rigid substrate, such as a glass substrate or a polyimide substrate. The buffer layer is a multilayer film structure composed of a material such as SiOₓ or SiNₓ. The thin film transistors are used to control the display of the display screen. A thin film transistor generally includes two metal layers, two insulating layers, an active layer, and an ohmic contact layer.

The light emitting device layer 32 is disposed on the array substrate 31. The light emitting device layer 32 includes an anode layer, an organic light emitting layer, and a cathode layer which are sequentially stacked, wherein the anode layer is disposed on the array substrate 31. The organic light emitting layer is composed of an electron transport layer (ETL), a light emitting layer (EL), and a hole transport layer (HTL). The constituent material of the cathode layer includes one or more of metals, such as lithium, calcium, lithium, aluminum, and silver. The constituent material of the anode layer is a metal oxide, such as indium tin oxide.

The thin film encapsulation layer 33 is disposed on the light emitting device layer 32. The thin film encapsulation layer 33 is composed of a material such as SiNₓ or SiO₂. The thin film encapsulation layer 33 serves to protect the structure of the light emitting device layer 32, the array substrate 31, and the like in the display screen 2 from moisture and oxygen.

The discharge layer 34 is disposed on the thin film encapsulation layer 33. The discharge layer 34 is made of a conductive material, such as a metal material, a conductive non-metal material, a semiconductor material, or the like. In one embodiment, the conductive material is a transparent conductive material, such as indium tin oxide (ITO). In one embodiment, the conductive material is a conductive material having a higher impedance, and a range of the impedance of the discharge layer 11 is 10⁸-10⁹ ohms.

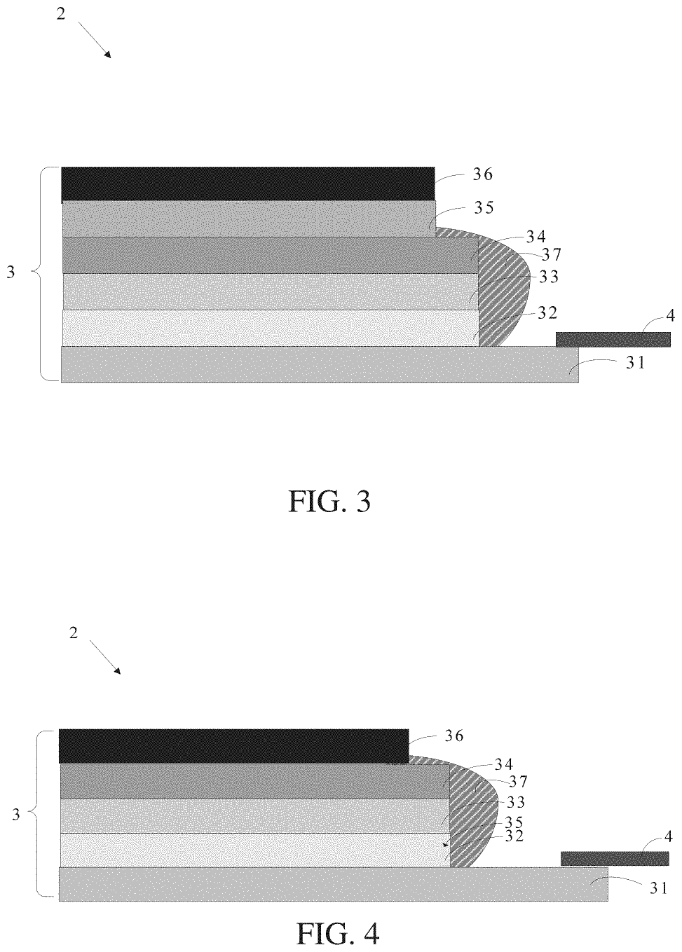

The discharge layer 34 is connected to a ground trace in the display screen, wherein the ground trace is a ground line, or a source and drain traces grounded through a flexible circuit board 4. Specifically, a conductive line 37 can be disposed along a height direction of the display screen of the stacked structure, and the discharge layer 34 is connected to the ground trace through the conductive line 37 as shown in FIGS. 3-4. When the display screen is in an environment with a lot of static electricity, the discharge layer 34 discharges the static electricity.

In some embodiments, the display screen 3 further comprises a touch electrode layer 35 as shown in FIGS. 2-4, wherein the touch electrode layer 35 includes a plurality of touch sensing lines and a plurality of driving sensing lines, and the touch electrode layer 35 is used to implement a touch function.

In some embodiments, the touch electrode layer 35 is disposed on the thin film encapsulation layer 33, and the discharge layer 34 is disposed on the touch electrode layer 35 as shown in FIG. 2. The display screen 3 is a touch screen of an on-cell structure. At this time, the discharge layer 34 is disposed above the touch electrode layer 35, and a range of the impedance of the discharge layer 34 can be set 10⁸-10⁹ ohms, so that the signal of the touch electrode layer 35 can be prevented from being shielded. Furthermore, it is also possible to avoid interference of the liquid crystal in the liquid crystal display device with an external electric field.

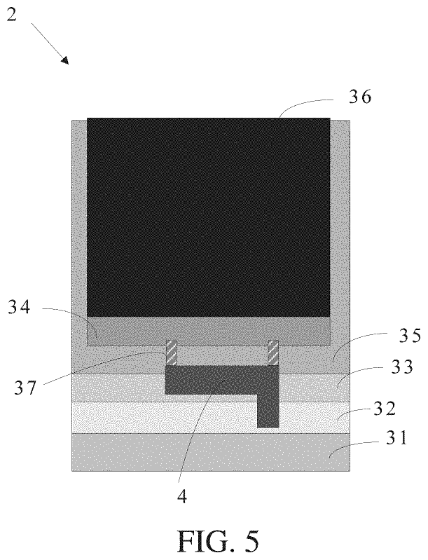

In the display screen 3 of the on-cell structure, the ground trace includes a ground line disposed at an edge of the touch electrode layer 35. The discharge layer 34 is connected to the ground line. Specifically, the discharge layer 34 is connected to the ground line through the conductive line 37, and the ground line is grounded through the flexible circuit board 4 disposed on the touch electrode layer 35 as shown in FIG. 5. As described above, the discharge layer 34 can discharge the static electricity received by the display screen 3 when the display screen 3 is in an environment with a lot of static electricity.

In some embodiments, the touch electrode layer 35 is disposed on the discharge layer 34 as shown in FIG. 3, and the display screen 3 is a touch screen of an out-cell structure. At this time, the touch electrode layer 35 is disposed above the discharge layer 34, and a range of the impedance of the discharge layer 34 can be set to be between 100 and 150 ohms, so that the discharge layer 34 has better antistatic performance.

In some embodiments, the touch electrode layer 35 is integrated on the light emitting device layer 32 as shown in FIG. 4, and the display screen 3 is a touch screen of an in-cell structure. Specifically, the cathode layer located in the light emitting device layer 32 is patterned to generate a touch function, and the cathode is equivalent to the touch electrode layer 35. At this time, the discharge layer 34 is disposed above the touch electrode layer 35, and a range of the impedance of the discharge layer 34 can be set 10⁸-10⁹ ohm. It can prevent the signal of the touch electrode layer 35 from being shielded. Furthermore, it is also possible to avoid interference of the liquid crystal in the liquid crystal display device with an external electric field.

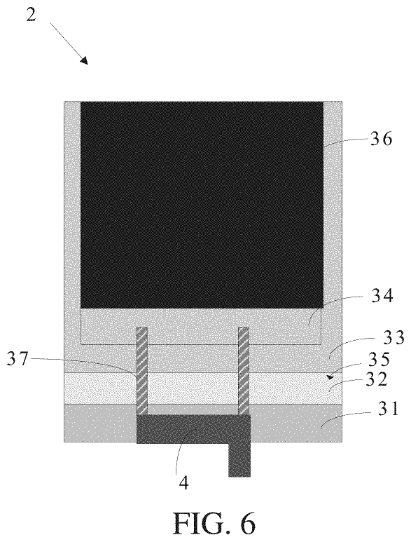

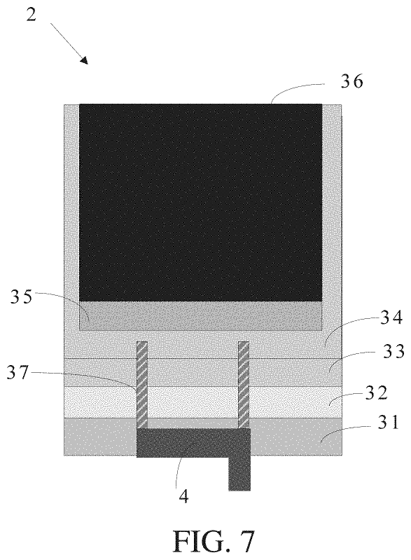

Referring to FIGS. 3-4, in the display panel 3 of the out-cell structure and the in-cell structure, the ground traces include source and drain traces, and the source and drain traces are disposed at an edge of the array substrate 31. Referring to FIGS. 6-7, the discharge layer 34 is connected to the source and drain traces through the conductive lines 37, and the source and drain traces are grounded through the flexible wiring board 4 disposed on the array substrate 1. The discharge layer 34 is connected to the source and drain traces. When the display screen 3 is in an environment with a lot of static electricity, the discharge layer 34 discharges the static electricity.

In some embodiments, the display screen 3 further includes a polarizer 36 as shown in FIGS. 2-4. The polarizer 36 is configured to transmit light that vibrates in a certain direction, wherein the polarizer 36 is a transmissive polarizing layer, a reflective polarizing layer or a semi-transmissive polarizing layer, and the type of the polarizer 36 is not specifically limited herein.

Referring to FIG. 2, when the touch electrode layer 35 is disposed on the thin film encapsulation layer 33 and the discharge layer 34 is disposed on the touch electrode layer 35, the polarizer 36 is disposed on the discharge layer 34. Referring to FIG. 3, when the touch electrode layer 35 is disposed on the discharge layer 34, the polarizer 36 is disposed on the touch electrode layer 35. Referring to FIG. 4, when the touch electrode layer 35 is integrated on the light emitting device layer 32, the polarizer 36 is disposed on the discharge layer 34.

The display screen and the display screen module of the embodiment of the invention disclosure improve the antistatic performance of the display screen by disposing the discharge layer connected to the grounding trace.

The present disclosure has been described with preferred embodiments thereof and it is understood that many changes and modifications to the described embodiments can be carried out without departing from the scope and the spirit of the invention that is intended to be limited only by the appended claims.

What is claimed is:

1. A polarizer used for a display screen, comprising:
a discharge layer; and
a polarizing layer disposed on the discharge layer;
wherein the discharge layer is connected to a ground trace in the display screen.

2. The polarizer according to claim 1, wherein the discharge layer has an impedance, and a range of the impedance is 10⁸-10⁹ ohms.

3. A display screen, comprising:
an array substrate;
a light emitting device layer;
a thin film encapsulation layer;
a discharge layer; and
a ground trace;
wherein the light emitting device layer is disposed on the array substrate;
wherein the thin film encapsulation layer is disposed on the light emitting device layer;
wherein the discharge layer is disposed on the thin film encapsulation layer, and
the discharge layer is connected to the ground trace.

4. The display screen according to claim 3, wherein the display screen further comprises a touch electrode layer;
the touch electrode layer is disposed on the thin film encapsulation layer, and
the discharge layer is disposed on the touch electrode layer; or
the touch electrode layer is disposed on the discharge layer; or
the touch electrode layer is integrated on the light emitting device layer.

5. The display screen according to claim 4, wherein the light emitting device layer comprises a cathode layer;
the touch electrode layer is formed after the cathode layer is patterned.

6. The display screen according to claim 4, wherein the display screen further comprises a polarizer;
when the touch electrode layer is disposed on the thin film encapsulation layer and the discharge layer is disposed on the touch electrode layer, the polarizer is disposed on the discharge layer;
when the touch electrode layer is disposed on the discharge layer, the polarizer is disposed on the touch electrode layer;
when the touch electrode layer is integrated on the light emitting device layer, the polarizer is disposed on the discharge layer.

7. The display screen according to claim 4, wherein the discharge layer has an impedance, and a range of the impedance is 100 to 150 ohms when the touch electrode layer is disposed above the discharge layer;
a range of the impedance is 10⁹-10⁹ ohms when the discharge layer is disposed above the touch electrode layer.

8. The display screen according to claim 4, wherein when the touch electrode layer is disposed on the thin film encapsulation layer, and the discharge layer is disposed on the touch electrode layer, the ground trace includes a ground line, and the ground line is disposed at an edge of the touch electrode layer.

9. The display screen according to claim 4, wherein when the touch electrode layer is disposed on the discharge layer or the touch electrode layer is integrated on the light emitting device layer, the ground trace includes a source and drain trace, and the source and drain trace is disposed on the array substrate.

10. The display screen according to claim 3, wherein a composition material of the discharge layer includes a transparent conductive material.

11. A display screen module, comprising:
a display screen; and
a flexible circuit board bonded to the display screen;
wherein the display screen comprises an array substrate, a light emitting device layer, a thin film encapsulation layer, a discharge layer, and a ground trace;
wherein the light emitting device layer is disposed on the array substrate;
wherein the thin film encapsulation layer is disposed on the light emitting device layer;
wherein the discharge layer is disposed on the thin film encapsulation layer, and the discharge layer is connected to the ground trace;
a ground trace in the display screen is grounded through the flexible circuit board.

12. The display screen module according to claim 11, wherein the display screen further comprises a touch electrode layer;
the touch electrode layer is disposed on the thin film encapsulation layer, and
the discharge layer is disposed on the touch electrode layer; or
the touch electrode layer is disposed on the discharge layer; or
the touch electrode layer is integrated on the light emitting device layer.

13. The display screen module according to claim 12, wherein the light emitting device layer comprises a cathode layer;
the touch electrode layer is formed after the cathode layer is patterned.

14. The display screen module according to claim 12, wherein the display screen further comprises a polarizer;
when the touch electrode layer is disposed on the thin film encapsulation layer and the discharge layer is disposed on the touch electrode layer, the polarizer is disposed on the discharge layer;
when the touch electrode layer is disposed on the discharge layer, the polarizer is disposed on the touch electrode layer;
when the touch electrode layer is integrated on the light emitting device layer, the polarizer is disposed on the discharge layer.

15. The display screen module according to claim 12, wherein the discharge layer has an impedance, and a range of the impedance is 100 to 150 ohms when the touch electrode layer is disposed above the discharge layer;
a range of the impedance is 10⁹-10⁹ ohms when the discharge layer is disposed above the touch electrode layer.

16. The display screen module according to claim 12, wherein when the touch electrode layer is disposed on the thin film encapsulation layer, and the discharge layer is disposed on the touch electrode layer, the ground trace includes a ground line, and the ground line is disposed at an edge of the touch electrode layer.

17. The display screen module according to claim 12, wherein when the touch electrode layer is disposed on the discharge layer or the touch electrode layer is integrated on the light emitting device layer, the ground trace includes a source and drain trace, and the source and drain trace is disposed on the array substrate.

18. The display screen module according to claim 11, wherein a composition material of the discharge layer includes a transparent conductive material.
